(19) United States
(12) Patent Application Publication
(10) Pub. No.: US 2009/0220106 A1
(43) Pub. Date: Sep. 3, 2009

(54) AUDIO SIGNAL PROCESSING CIRCUIT

(75) Inventors: Mitsuteru Sakai, Kyoto (JP); Yosuke Sato, Kyoto (JP)

Correspondence Address: CANTOR COLBURN, LLP, 20 Church Street, 22nd Floor, Hartford, CT, 06103, US

(73) Assignee: ROHM CO., LTD., Kyoto (JP)

(21) Appl. No.: 12/396,304

(22) Filed: Mar. 2, 2009

(30) Foreign Application Priority Data
Feb. 29, 2008 (JP) 2008-050177

(51) Int. Cl. H04B 15/00; H03G 3/00

(52) U.S. Cl. 381/94.5; 381/104

(57) ABSTRACT

A first amplifier amplifies a first audio signal. A synthesizer circuit synthesizes an output signal of the first amplifier with a second audio signal. The first amplifier is arranged such that a first state in which the first amplifier amplifies a signal with a set gain and a second state in which the first amplifier outputs a fixed bias voltage can be seamlessly switched. A signal processing unit is disposed upstream of the first amplifier, subjects a third audio signal to a predetermined signal process, and outputs it as the first audio signal. When a state of the signal processing unit is switched, the first amplifier is changed from the first state to the second state, the state of the signal processing unit is switched in the second state, and subsequently the first amplifier is switched from the second state to the first state.

### BACKGROUND OF THE INVENTION

1. Field of the Invention

The present invention relates to an audio signal processing circuit which processes an audio signal.

2. Description of the Related Art

Electronic equipment such as a CD player, an audio amplifier, a car stereo, a mobile radio, a mobile audio player, and the like having a function which reproduces an audio signal ordinarily has a volume for adjusting a sound, an equalizer which adjusts frequency characteristics, a tone control function, and the like. The volume and the equalizer are controlled by changing amplitude of the audio signal.

For example, the tone control is performed by correcting the band of an audio signal to be processed and synthesizing the corrected signal with the original audio signal.

[Patent Document 1] Japanese Patent Application Laid-Open Publication No. 2005-117489

[Patent Document 2] Japanese Patent Application Laid-Open Publication No. 2005-217710

[Patent Document 3] Japanese Patent Application Laid-Open Publication No. 2004-222077

[Patent Document 4] Japanese Patent Application Laid-Open Publication No. 11-340759

[Patent Document 5] Japanese Patent Application Laid-Open Publication No. 2003-283262

When a cut-off frequency and a Q value are discretely switched in a stage in which a band is corrected at the time the tone control is performed, an audio signal is made discontinuous and the amplitude thereof is abruptly changed, from which a problem arises in that noise (which is called shock noise) is output from an electroacoustic conversion device such as a speaker, a headphone, and the like.

Further, when two audio signals are mixed, one of the audio signals is turned on and the other of them is turned off, an audio signal obtained by mixing the above audio signals is abruptly changed and shock noise is generated thereby.

### SUMMARY OF THE INVENTION

A general purpose of the present invention, which was made in view of the problem according to the present invention, is to provide an audio signal processing circuit which suppresses noise.

An audio signal processing circuit of an embodiment of the present invention has a first amplifier which amplifies a first audio signal and a synthesizer circuit which synthesizes an output signal of the first amplifier with a second audio signal. The first amplifier is configured to seamlessly switch a first state in which the first amplifier amplifies a signal with a set gain and a second state in which the first amplifier outputs a fixed bias voltage.

According to the embodiment, noise of an output signal of the synthesizer circuit can be suppressed by shifting the first amplifier to the second state before the timing at which discontinuous points and an abrupt change occur to the first audio signal. In the specification, “amplification” is a concept including an attenuation in a case that a gain is 1 and further a case that the gain is smaller than 1 in addition to a case that the gain is larger than 1.

An audio signal processing circuit of an embodiment may further have a signal processing unit which is disposed upstream of the first amplifier, subjects a third audio signal to a predetermined signal process, and outputs the third audio signal as the first audio signal. When a state of the signal processing unit is switched, the first amplifier may be changed from the first state to the second state, the state of the signal processing unit may be switched in the second state, and subsequently the first amplifier may be switched from the second state to the first state.

The signal processing unit may be a filter. In this case, noise, which is caused when a cut-off frequency, a band, a Q value, and the like of the filter are discretely switched, can be suppressed.

The signal processing unit may be input with the same signal as the second audio signal as the third audio signal.

The first amplifier may be a variable gain amplifier. When a gain of the first amplifier is switched from a present value to a target value, the first amplifier may be changed from the first state to the second state, the gain of the first amplifier may be switched from the present value to the target value in the second state, and subsequently the first amplifier may be changed from the second state to the first state.

The audio signal processing circuit may be a mixer circuit which mixes the first audio signal with the second audio signal. In this case, noise, which is caused when the first audio signal is turned on and off, can be suppressed.

The first amplifier may include an amplifier which amplifies the first audio signal by a set gain, a bias voltage generating circuit which outputs the predetermined bias voltage, and a soft switching circuit which receives an output of the amplifier at a first input terminal, receives the bias voltage at a second input terminal, and gently shifts an output of the soft switching circuit from one of the input terminals to the other input terminal. In this case, a first state in which the first input terminal is selected can be smoothly switched to a second state in which the second input terminal is selected.

It is to be noted that any arbitrary combination or rearrangement of the above-described structural components and so forth is effective as and encompassed by the present embodiments. Moreover, this summary of the invention does not necessarily describe all necessary features so that the invention may also be a sub-combination of these described features.

A noise can be suppressed according to the audio signal processing circuit of the present invention.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a block diagram showing an arrangement of an audio signal processing circuit according to a first embodiment;

FIG. 2 is a block diagram showing an example of an arrangement of a first amplifier;

FIGS. 3A and 3B are time charts showing operating conditions of the audio signal processing circuit of FIG. 1 and an audio signal processing circuit of a comparative example;

FIG. 4 is a block diagram showing an arrangement of an audio signal processing circuit according to a modification of the first embodiment; and

FIG. 5 is a block diagram showing an arrangement of an audio signal processing circuit according to a second embodiment.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

In the specification, “a state in which a member A is connected to a member B” also includes a case in which the member A is directly and physically connected to the member B and a case in which the member A is indirectly connected to the member B through other member which does not affect an electrically connected state. Likewise, “a state in which a member C is interposed between the member A and the member B” also includes a case in which the member A is indirectly connected to the member C or the member B is connected to the member C through other member which does not affect an electrically connected state, respectively in addition to a case in which the member A is directly connected to the member C or the member B is directly connected to the member C.

### First Embodiment

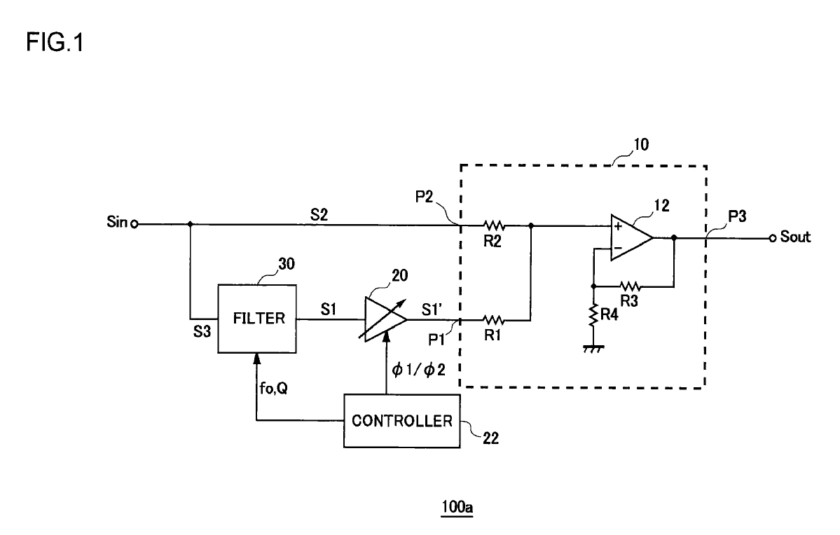

FIG. 1 is a block diagram showing an arrangement of an audio signal processing circuit 10a according to a first embodiment.

The audio signal processing circuit 100a subjects an input audio signal Sin to a predetermined signal process and outputs an output audio signal Sout. Specifically, the input audio signal Sin is branched to two subsignals, and one of the subsignals is subjected to the signal process and output after it is synthesized with the other subsignal. A tone control is exemplified as an example of the signal process.

The audio signal processing circuit 100a has a synthesizer circuit 10, a first amplifier 20, a controller 22, and a signal processing unit 30.

The first amplifier 20 amplifies a first audio signal S1 input thereto. The synthesizer circuit 10 has two inputs, and an output signal S1′ from the first amplifier 20 is input to one of the inputs and a second audio signal S2 is input to the other input. The second audio signal S2 is the input audio signal Sin of the audio signal processing circuit 100a. The synthesizer circuit 10 synthesizes the first audio signal S1′ with the second audio signal S2. Synthesization means an addition process, a subtraction process, an average process, a partial process, and the like.

In the first embodiment, the synthesizer circuit 10 is an addition circuit which uses an operational amplifier 12. The synthesizer circuit 10 has input terminals P1 and P2, synthesizes the signals S2 and S1′ input thereto, respectively, and outputs a synthesized signal from an output terminal P3. The synthesizer circuit 10 has the operational amplifier 12 and first to fourth resistors R1 to R4. The third resistor R3 is interposed between an inverted input terminal and the output terminal of the operational amplifier 12, and the fourth resistor R4 is interposed between the inverted input terminal and a fixed voltage terminal (ground terminal). The first resistor RI is interposed between a non-inverted input terminal and the input terminal P1 of the operational amplifier 12, and the second resistor R2 is interposed between the non-inverted input terminal and the input terminal P2 of the operational amplifier 12.

The synthesized signal shown by the following expression is output from the output terminal P3 of the synthesizer circuit 10.

Sout=(R2·S1′+S2·R1)/(R1+R2)×(R3+R4)/R4

Note that the synthesizer circuit 10 may be simply composed of a partial circuit and other addition circuit using a resistor.

The first amplifier 20 is arranged such that a first state φ1 which has a set gain and a second state φ2 which outputs a fixed bias voltage Vbias can be seamlessly switched. The states φ1 and φ2 of the first amplifier 20 are controlled by the controller 22.

The audio signal processing circuit 100a is basically arranged as described above. Subsequently, a basic operation of the audio signal processing circuit 100a will be described.

It is assumed now that the first amplifier 20 is set to the first state φ1, and the first audio signal S1 is in a stable state. Before the timing at which discontinuous points and an abrupt change occur to the first audio signal S1, the controller 22 gently and seamlessly changes the first amplifier 20 from the first state φ1 to the second state φ2. After the first audio signal S1 is stabilized, the first amplifier 20 is changed from the second state φ2 to the first state φ1 again.

According to the basic arrangement of the audio signal processing circuit 100a, since an abrupt change of the first audio signal S1 does not affect the output signal Sout, noise can be suppressed. Further, since the second audio signal S2 is continuously output as the output audio signal Sout, uncomfortable feeling and unnaturalness can be reduced in audibility.

The arrangement of the audio signal processing circuit 10a will be further described. The signal processing unit 30 is disposed upstream of the first amplifier 20 to subject a third audio signal S3 to a predetermined signal process and outputs the third audio signal S3 as the first audio signal S1.

When a state of the signal processing unit 30 is switched, the controller 22 changes the first amplifier 20 from the first state φ1 to the second state φ2 before the state of the signal processing unit 30 is switched. Then, the state of the signal processing unit 30 is switched in the second state φ2. Subsequently, the signal processing unit 30 is switched from the second state φ2 to the first state φ1.

When the audio signal processing circuit 10a performs a tone control process, the signal processing unit 30 is arranged as a filter which can discretely switch frequency characteristics. A band-pass filter (BPF), a low-pass filter (LPF), a high-pass filter (HPF), and a band elimination filter (BEF) are exemplified as the filter. The frequency characteristics means a center frequency (or a cut-off frequency) fo, the Q value, and the like. It is needless to say that the process performed by the signal processing unit 30 is not limited to the above process, and the signal processing unit 30 can be applied to various signal processes.

In the audio signal processing circuit 100a having the tone control function, the signal processing unit 30 is input with the same signal as the second audio signal S2, i.e., the input signal Sin as the third audio signal S3. The signal processing unit 30 amplifies a specific frequency of the input signal Sin or eliminates an unnecessary band from the input signal Sin and outputs it as the first audio signal S1.

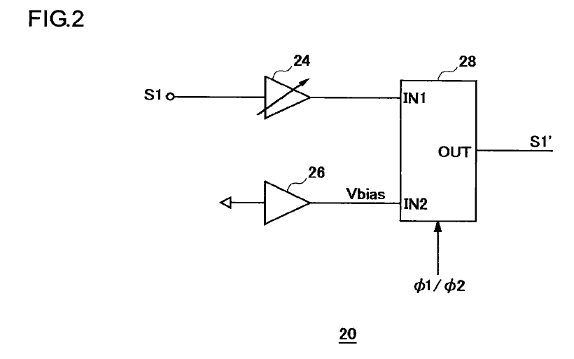

FIG. 2 is a block diagram showing an example of an arrangement of the first amplifier. The first amplifier 20 includes an amplifier 24, a bias voltage generating circuit 26, and a soft switching circuit 28.

The amplifier 24 amplifies the first audio signal S1 by a set gain. The bias voltage generating circuit 26 outputs a predetermined bias voltage Vbias. Both the amplifier 24 and the bias voltage generating circuit 26 may be arranged as inverted amplifiers or as non-inverted amplifiers each making use of an operational amplifier. When the tone control is performed, a tone gain can be adjusted by arranging the amplifier 24 as a variable gain amplifier.

The soft switching circuit 28 receives an output signal of the amplifier 24 at a first input terminal IN1 and receives the bias voltage Vbias at a second input terminal IN2. The soft switching circuit 28 gently shifts an output OUT thereof from one of the input terminals to the other input terminal in response to a control signal from the controller 22. Various known switching circuits can be used as the soft switching circuit 28.

The audio signal processing circuit 100a is arranged as described above in its entirety. Subsequently, an operation of the audio signal processing circuit 100a will be described.

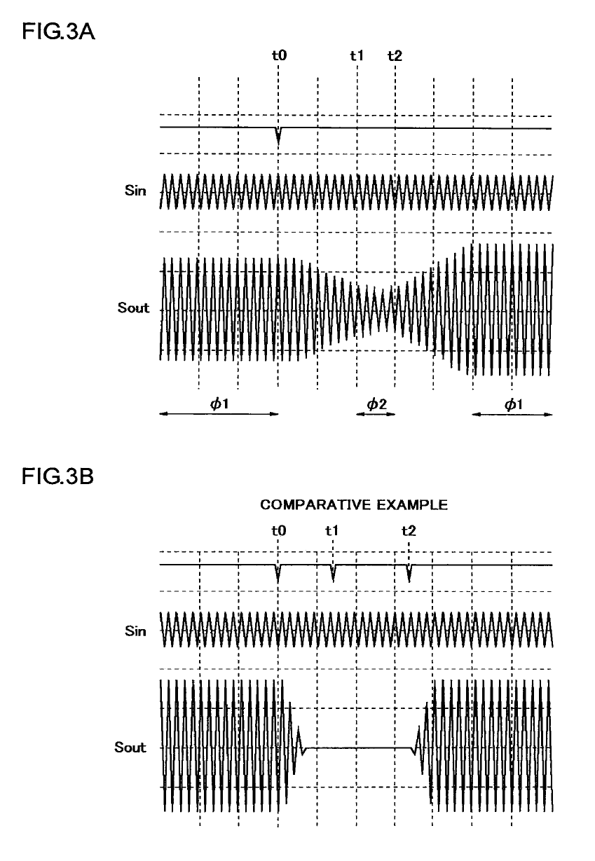

FIGS. 3A and 3B are time charts showing operating conditions of the audio signal processing circuit of FIG. 1 and an audio signal processing circuit of a comparative example.

A process of the comparative example will be described first referring to FIG. 3B to clarify an advantage of the present invention. In the process of the comparative example, the frequency characteristics of a signal processing unit 30 are set to a certain state before a time t0. When it is indicated to change the frequency characteristics at the time t0, an output of an audio signal processing circuit is gently switched to a mute state. After the output of the audio signal processing circuit is made to the mute state, the frequency characteristics of the signal processing unit 30 or the tone gain thereof is switched to different state at a time t1. Thereafter, the mute state is released at a time t2, and the audio signal Sout is output again. Since the audio signal is muted each time the state of the tone control is switched, a user feels uncomfortably.

In the comparative example, a mute circuit is additionally required and a micro processor (host processor), which controls the audio signal processing circuit, must output a control signal to the audio signal processing circuit as well as must output the control signal also to the mute circuit, from which a problem arises in that a load on the micro processor is increased.

Subsequently, an operation of the audio signal processing circuit 100a according to the first embodiment will be described referring to FIG. 3A. The frequency characteristics and the tone gain of the signal processing unit 30 are set to certain states before a time t0, and the first amplifier 20 is set to the first state φ1 before the time t0. When it is indicated to change the frequency characteristics or the tone gain at the time t0, the first amplifier 20 is gently switched from the first state φ1 to the second state φ2. Thereafter, when the first amplifier 20 is switched to the second state φ2 at the time t1, the frequency characteristics or the tone gain of the signal processing unit 30 is instantly switched to a different state. Thereafter, the first amplifier 20 is shifted from the second state φ2 to the first state φ1 again.

As described above, in the audio signal processing circuit 100a according to the first embodiment, even if the state of the signal processing unit 30 or the gain (tone gain) of the amplifier 24 in the first amplifier 20 is instantly switched, the output audio signal Sout is not muted, and the input audio signal Sin is continuously output. Accordingly, since the user is unlike to be aware of the control for switching the tone, the value of the audio signal processing circuit employed in an audio device can be improved.

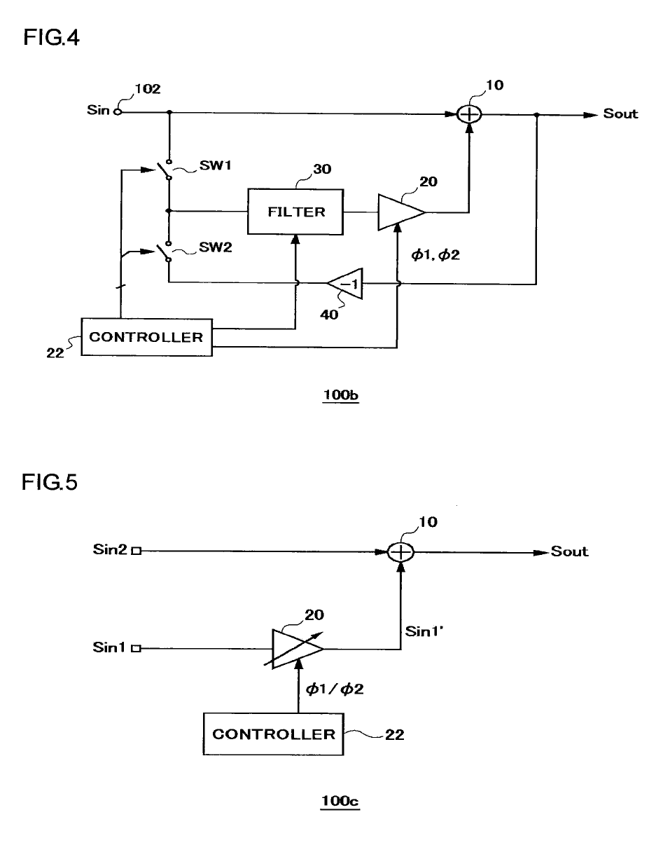

FIG. 4 is a block diagram showing an arrangement of an audio signal processing circuit 100b according to a modification of the first embodiment.

The audio signal processing circuit 100b has an inverted amplifier 40, a first switch SW1, and a second switch SW2 in addition to the arrangement of the audio signal processing circuit 100a of FIG. 2. A signal processing unit 30 is a filter which can switch frequency characteristics. The inverted amplifier 40 inverts the phase of an output audio signal Sout. The first switch SW1 is interposed between an input terminal 102 of the input audio signal Sin and an input terminal of the signal processing unit 30. The second switch SW2 is interposed between an output terminal of the inverted amplifier 40 and the input terminal of the signal processing unit 30.

The controller 22 switches turned-on/turned-off states of the first switch SW1 and the second switch SW2 in addition to that it switches the frequency characteristics of the signal processing unit 30 and switches between the first state φ1 and the second state φ2 of the first amplifier 20.

When the first switch SW1 is turned on, since it is equivalent with the audio signal processing circuit 100a of FIG. 1, the frequency band set by the signal processing unit 30 is boosted. On the contrary, when the second switch SW2 is turned off, the frequency band set by the signal processing unit 30 is cut.

The controller 22 sets the first amplifier 20 to the second state φ2 before the timing at which the input signal of the first amplifier 20 is made discontinuous or before the timing at which the gain of the amplifier 24 in the first amplifier 20 is switched and returns the first amplifier 20 to the first state φ1 after the input signal is stabilized. The input signal of the first amplifier 20 is made discontinuous when the frequency characteristics of the signal processing unit 30 are switched or when the first switch SW1 and the second switch SW2 are switched from a turned-on state or a turned-off state.

According to the modification of FIG. 4, occurrence of shock noise can be preferably prevented at the timing at which a specific frequency band is switched from a boosted state to a cut state and vice versa in addition to the advantage of the audio signal processing circuit 100a of FIG. 1.

### Second Embodiment

The first embodiment has explained about the signal processing circuit for performing the tone control. The audio signal processing circuit 100c according to a second embodiment relates to a mixer circuit for mixing a first input audio signal Sin1 with a second input audio signal Sin2.

FIG. 5 is a block diagram showing an arrangement of the audio signal processing circuit 100c according to the second embodiment.

The audio signal processing circuit 100c has a synthesizer circuit 10, a first amplifier 20, and a controller 22.

The first amplifier 20 amplifies the first input audio signal Sin1 by a predetermined gain and outputs it to the synthesizer circuit 10. The first amplifier 20 can switch between the first state φ1 and the second state φ2 likewise the first embodiment. The controller 22 switches between the first state φ1 and the second state φ2 of the first amplifier 20.

To change a mixing ratio, the first amplifier 20 is arranged as a variable gain amplifier so that it can discretely switches a gain. The controller 22 also switches the gain of the first amplifier 20. In this case, an amplifier 24 in the first amplifier 20 is preferably arranged as a variable gain amplifier.

The synthesizer circuit 10 synthesizes the second input audio signal Sin2 with an amplified first input audio signal Sin1′.

An operation of the audio signal processing circuit 100c arranged as described above will be described.

When the gain of the first amplifier 20 is switched from a present value to a target value, first, the first amplifier 20 is switched from the first state φ1 to the second state φ2. Subsequently, in the second state φ2, the gain of the first amplifier 20 is switched from the present value to the target value. Then, the synthesizer circuit is switched from the second state φ2 to the first state φ1.

According to the audio signal processing circuit 100c of FIG. 5, occurrence of a shock sound (noise) can be suppressed when the mixing ratio is switched. Further, since the second input audio signal Sin2 is continuously output, i.e., since audio is not disconnected, mixing can be switched seamlessly while reducing unnaturalness in audibility.

As a modification of the audio signal processing circuit 100c of FIG. 5, a second amplifier similar to the first amplifier 20 may be also disposed to the second input audio signal Sin2 side. In this case, the mixing ratio can be changed by changing the amplitudes of both the first input audio signal Sin1 and the second input audio signal Sin2.

While the preferred embodiments of the present invention have been described using specific terms, such description is for illustrative purposes only, and it is to be understood that changes and variations may be made without departing from the spirit or scope of the appended claims.

What is claimed is:

1. An audio signal processing circuit comprising:
a first amplifier which amplifies a first audio signal; and
a synthesizer circuit which synthesizes an output signal of the first amplifier with a second audio signal, wherein
the first amplifier is configured to seamlessly switch a first state in which the first amplifier amplifies a signal with a set gain and a second state in which the first amplifier outputs a fixed bias voltage.

2. The audio signal processing circuit according to claim 1, further comprising a signal processing unit which is disposed upstream of the first amplifier, subjects a third audio signal to a predetermined signal process, and outputs the third audio signal as the first audio signal, wherein
when a state of the signal processing unit is switched, the first amplifier is switched from the first state to the second state, the state of the signal processing unit is switched in the second state, and subsequently the first amplifier is switched from the second state to the first state.

3. The audio signal processing circuit according to claim 2,
wherein the signal processing unit is a filter.

4. The audio signal processing circuit according to claim 3,
wherein the signal processing unit is input with the same signal as the second audio signal as the third audio signal.

5. The audio signal processing circuit according to claim 3,
wherein the signal processing unit is input with a signal obtained by inverting an output of the synthesizer circuit as the third audio signal.

6. The audio signal processing circuit according to claim 1,
wherein the first amplifier is a variable gain amplifier, wherein when a gain of the first amplifier is switched from a present value to a target value, the first amplifier is changed from the first state to the second state, the gain of the first amplifier is switched from the present value to the target value in the second state, and subsequently the first amplifier is changed from the second state to the first state.

7. The audio signal processing circuit according to claim 3,
wherein the audio signal processing circuit is a mixer circuit which mixes the first audio signal with the second audio signal.

8. The audio signal processing circuit according to claim 1,
wherein the first amplifier comprises:
an amplifier which amplifies the first audio signal by a set gain;
a bias voltage generating circuit which outputs the predetermined bias voltage; and
a soft switching circuit which receives an output of the amplifier at a first input terminal, receives the bias voltage at a second input terminal, and gently shifts an output of the soft switching circuit from a signal at one of the input terminals to a signal at the other input terminal.
